(19) United States
(12) Patent Application Publication
(10) Pub. No.: US 2013/0200519 A1
(43) Pub. Date: Aug. 8, 2013

(54) Through silicon via structure and method of fabricating the same

(71) Applicants: Ji Feng, Singapore (SG); Hailong Gu, Singapore (SG); Ying-Tu Chen, Singapore (SG); Jing-Ling Wang, Singapore (SG)

(72) Inventors: Ji Feng, Singapore (SG); Hailong Gu, Singapore (SG); Ying-Tu Chen, Singapore (SG); Jing-Ling Wang, Singapore (SG)

(21) Appl. No.: 13/364,331

(22) Filed: Feb. 2, 2012

(51) Int. Cl. H01L 23/48; H01L 21/768

(52) U.S. Cl. 257/751; 438/667; 257/E21.577; 257/E23.011

(57) ABSTRACT

The present invention relates to a method of fabricating a through silicon via (TSV) structure, in which, a dielectric layer is disposed to cover surface of each of a device region of a substrate and a sidewall and a bottom of a via hole in a TSV region of the substrate, and the via hole having the dielectric layer covering the sidewall and the bottom is filled with a conductive material. The present invention also relates to a TSV structure, in which, a dielectric layer disposed in the device region of a substrate extends to the via hole in a TSV region of the substrate to cover surface of the sidewall of the via hole to serve as a dielectric liner, and a conductive material is filled into the via hole having the dielectric layer covering the sidewall.

### BACKGROUND OF THE INVENTION

1. Field of the Invention

The present invention relates to a fabrication method and a structure of a through silicon via (TSV).

2. Description of the Prior Art

In the field of semiconductor technology, the response speed of IC circuits is related to the linking distance between devices disposed on a chip. For signal to be transmitted, the shorter the linking distance is, the faster the operational speed of a circuit device can be. Since the vertical distance between adjacent layers maybe much shorter than the width of a single-layer chip, IC circuits with a three-dimensional structure can shorten the linking distances of devices disposed on a chip. Accordingly, their operational speed can be increased when a chip is designed with a vertical packed structure in 3D IC schemes. In order to integrate different devices in one single stacked structure chip, interconnects are required between die and die to electrically connect the devices on each level. The through silicon via (TSV) is one of the novel semiconductor techniques developed for this purpose. TSV technique produces devices that meet the market trends of “light, thin, short and small” through the 3D stacking technique and also provides wafer-level packages utilized in micro electronic mechanic system (MEMS), photo-electronics and electronic devices.

Nowadays, the TSV structure is usually obtained by performing the following steps: first, forming via hole on the front side of a wafer by etching or laser process. Secondly, filling the via hole with a conductive material, such as polysilicon, copper or tungsten, to form a conductive path (i.e. the interconnect structure). Finally, the back side of the wafer, or die, is thinned to expose the conductive path. After the manufacture of the TSV, the wafers or dies are stacked together so that their conductive paths are connected to each other to provide electrical connection between wafers or dies. The 3D-stacked IC structure is accordingly obtained.

There is still a need for a novel and easy method for fabricating a TSV structure.

### SUMMARY OF THE INVENTION

One objective of the present invention is to provide a TSV structure and method for fabricating a TSV structure, in which the fabrication process is relatively easy.

According to an embodiment of the present invention, a method for fabricating a TSV structure includes steps as follows. First, a substrate is provided. The substrate includes a device region and a TSV region. A device is disposed in the device region. A via hole is disposed in the TSV region. The via hole includes a sidewall and a bottom. Next, a dielectric layer is formed to cover the device region and extend to the via hole to cover a surface of the sidewall and a surface of the bottom of the via hole. Thereafter, the via hole having the dielectric layer covering the sidewall and the bottom is filled with a conductive material.

According to another embodiment of the present invention, a TSV structure includes a substrate, a dielectric layer and a conductive material. The substrate includes a device region and a TSV region having a via hole having a sidewall. The dielectric layer is disposed on the substrate to cover the device region and extend to cover a surface of the sidewall of the via hole. The conductive material is filled into the via hole having the dielectric layer covering the sidewall.

According to an embodiment of the present invention, a via hole is formed in advance, and, after the via hole is formed, a dielectric layer is formed to cover a device region and a sidewall and a bottom of the via hole, such that the number of steps for the fabrication process can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 7 are schematic cross sectional views illustrating a method for fabricating a TSV structure according to an embodiment of the present invention.

### DETAILED DESCRIPTION

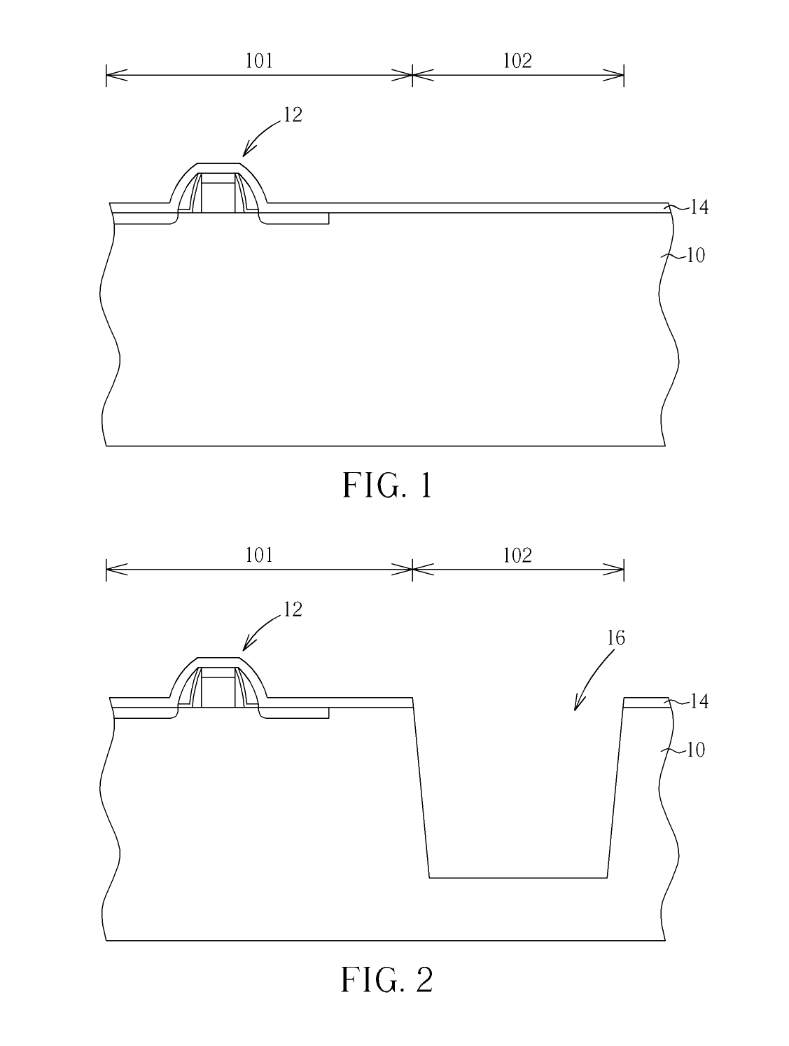

FIGS. 1-6 illustrate a method of fabricating a TSV structure according to an embodiment of the present invention. It should be noted that the drawing size of the figures does not in a real scale ratio and is just schematic for reference. The same elements of the embodiments may be marked with the same referral numbers. First, referring to FIG. 1, a substrate 10 is provided. The substrate 10 may comprise monocrystalline silicon, gallium arsenide (GaAs), or other material known in the art. The thickness of the substrate 10 may be substantially 700 to 1000 micrometers, but not limited thereto. The substrate 10 includes a device region 101 and a TSV region 102. A device 12, such as MOS transistor or other device or element, is disposed in the device region 101. A contact etch stop layer (CESL) 14 may be optionally disposed on the substrate 10 and the device 12. The CESL 14 may include for example silicon nitride, and it may protect the device 12 and further provide stress.

Next, referring to FIG. 2, a via hole 16 may be disposed in the TSV region 102. The via hole 16 maybe formed through for example photolithography and etch processes. It may have a size of about 10 micrometers (hole diameter)×about 60 micrometers (hole depth) . It should be noted that when the via hole 16 is disposed in the TSV region 102, the top surface of the device region 101 has not been planarized, and the top surface of the device region 101 is not flat.

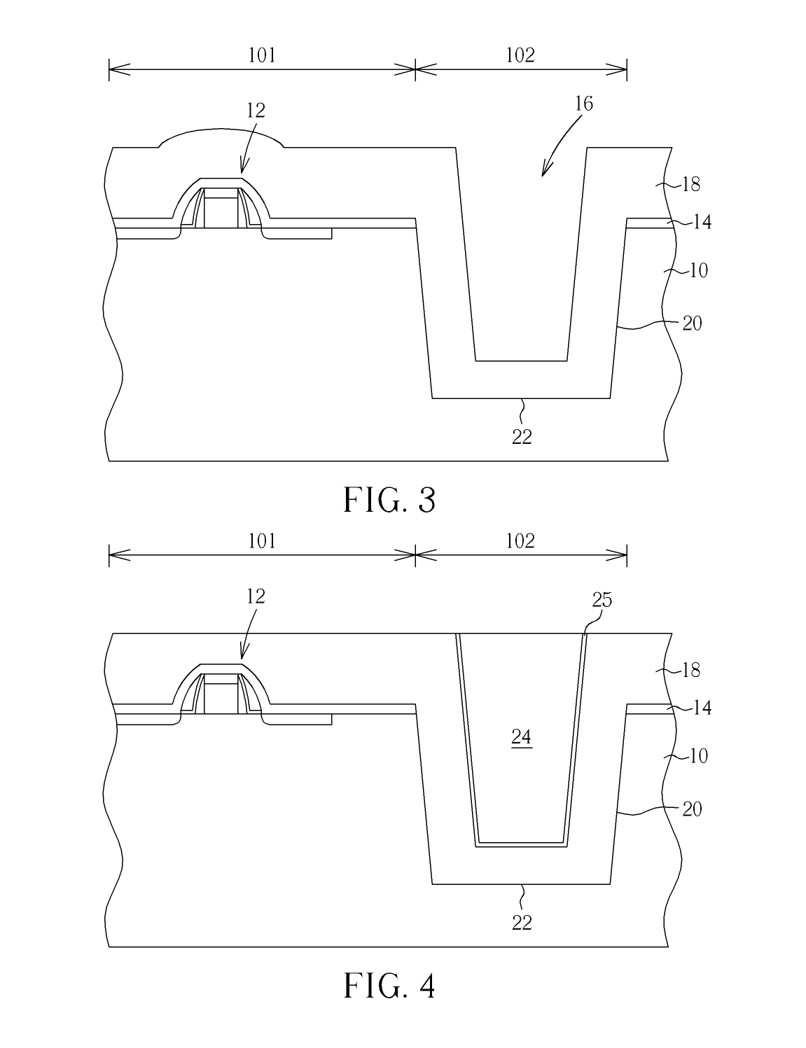

Thereafter, referring to FIG. 3, a dielectric layer 18 is formed. The dielectric layer 18 is allowed to cover the device region 101 and the TSV region 102. The dielectric layer 18 is formed to cover the device region 101 and the TSV region 102, such that it follows the surface profile of the device region 101 and the TSV region 102 and has the rise and fall corresponding to the rise and fall of the surface profile of the device region 101 and the TSV region 102. In detail, the dielectric layer 18 covers the surface of the substrate 10 and the device 12. If there have been already a CESL 14 or other device or element formed thereon, the dielectric layer 18 is allowed to cover it. The dielectric layer 18 above the substrate 10 may serve as an interlayer dielectric or at least one portion of an interlayer dielectric. Besides, the dielectric layer 18 is allowed to extend from the device region 101 to the via hole 16 in the TSV region 102 to cover the surface of the sidewall 20 and the surface of the bottom 22, and this portion may serve as a dielectric liner or at least one portion of a dielectric liner of the TSV structure. In other words, the dielectric layer 18 covers the sidewall 20 and the bottom 22 of the via hole 16 in the TSV region 102 and extends to the device region 101. In one embodiment according to the present invention, an interlayer dielectric extends to the via hole 16 for serving as a dielectric liner of a through silicon via. With respect to a relatively large size of the via hole 16, the dielectric layer 18 with a desirable thickness is not able to fill up the via hole 16, and there is still an opening within the via hole 16. The formation of the dielectric layer 18 may be similar to a conformal formation; however, the thickness at any place of the dielectric layer 18 can be the same as or different from the thickness at other place of the dielectric layer 18. All the top surface of the dielectric layer 18 above the substrate 10 in the device region 101 is preferably higher than the device 12, but not limited thereto.

The dielectric layer 18 may be formed using for example a deposition process. The dielectric layer 18 may include a single- or multi-layer structure. It may include for example silicon oxide, silicon nitride, silicon oxynitride or the like. In order to protect an underlying layer and maintain a prompt production, it is preferred that a thinner dielectric layer of a dense material for blocking the moisture is formed first for protecting underlying devices, elements, or structures, and then a thicker dielectric layer is formed on the thinner dielectric layer using a fast process. Since the thicker dielectric layer is formed fast, it tends to be relatively non-dense as compared with the underlying thinner dielectric layer. For example, in an embodiment, a relatively dense silicon oxide layer, such as phosphosilicate glass (PSG), having a thickness of about 250 angstroms may be formed on the device region 101 and the sidewall 20 and the bottom 22 of the via hole 16 through a sub-atmospheric pressure chemical vapor deposition (SACVD) in advance. Then, another silicon oxide layer is further formed on the aforesaid relatively dense silicon oxide layer through a plasma enhanced chemical vapor deposition (PECVD) using tetraethoxysilane (TEOS) as a silicon source. The latter silicon oxide layer may be relatively non-dense as compared with the former and have a thickness of about 3500 to about 4000 angstroms, but is not limited thereto.

Thereafter, referring FIG. 4, the via hole 16 having the dielectric layer 18 covering the sidewall 20 and the bottom 22 is filled with a conductive material 24 for forming a conductive electrode. Before the via hole 16 is filled with the conductive material 24, a barrier layer 25 may be optionally formed on the surface of the dielectric layer 18 within the via hole 16. The barrier layer 25 may include for example Ta, TaN (tantalum nitride), Ti, TiN or a combination thereof. A buffer layer is optionally disposed between the barrier layer 25 and the conductive material 24. The conductive material 24 may include for example polysilicon or a metal, such as Cu, W, Al, or other suitable material, and can be filled into or filled up the via hole 16 through for example electroplating, sputtering or other suitable process. Thereafter, a planarization, such as a CMP process, is optionally performed on the surface of the substrate 10, to grind the dielectric layer 18 and the conductive material 24 simultaneously to a predetermined thickness, so that the dielectric layer 18 is allowed to serve as an interlayer dielectric or a portion an interlayer dielectric.

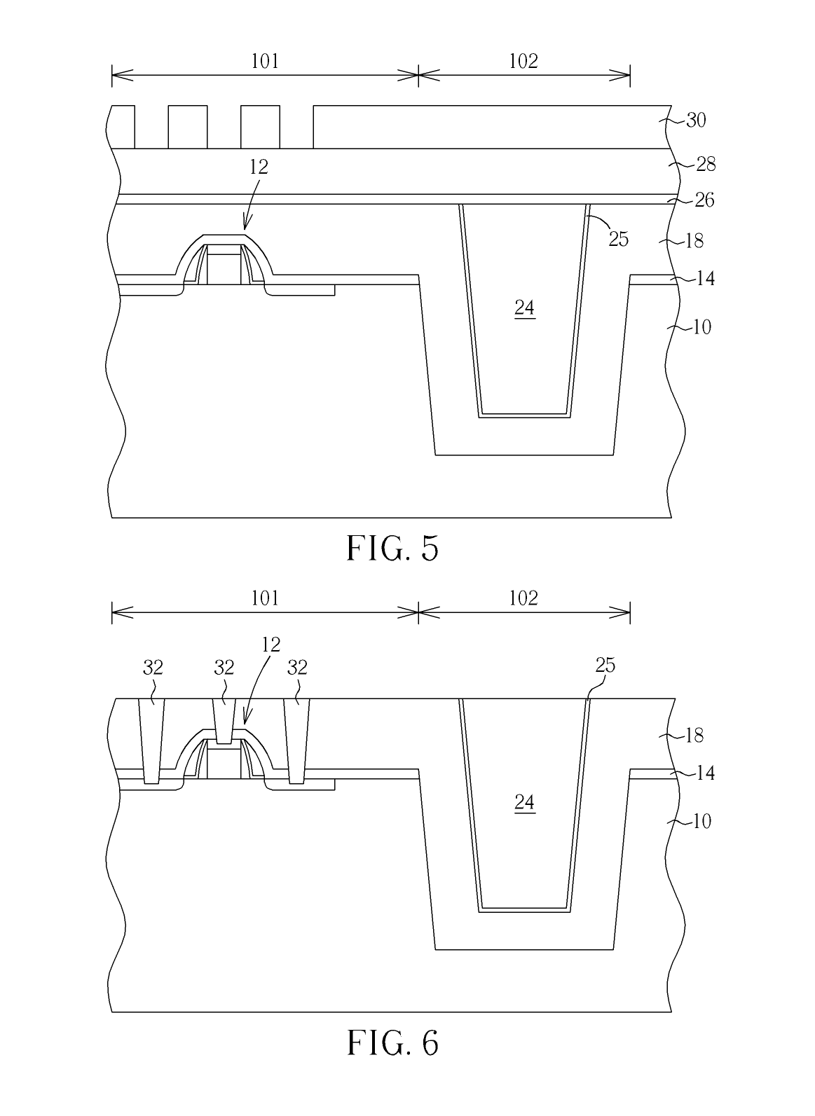

Thereafter, in the case that the device 12 in the device region 101 is a MOS transistor, at least one contact may be further formed. Referring FIGS. 5 and 6, before the contacts is formed, a cap layer 26 may be further formed on the surface of the planarized or unplanarized dielectric layer 18 and the conductive material 24 within the via hole 16. The cap layer 26 may protect the underlying layer during subsequent processes, but it is not a requisite. The formation of the contacts may be accomplished through, for example, forming a hard mask layer 28 covering the substrate 10, and the hard mask layer 28 is etched through a patterned photoresist layer 30 to form a pattern having at least an opening. The substrate 10 is etched through the opening to form contact holes through the cap layer 26, the dielectric layer 18 and the CESL 14 to expose a portion of the substrate 10 and/or a portion of the device 12 (such as the gate of the MOS transistor). The hard mask layer 28 is removed. Thereafter, a conductive material including for example Cu, W, Al or other suitable material is filled into the contact holes. A planarization, such as a CMP process, is optionally performed to finish the formation of contacts 32. The contacts 32 maybe allowed to connect the first layer of metal of the metal interconnect structure in subsequent processes. If the cap layer has been formed, the cap layer 26 above the conductive material 24 of the TSV structure may be also removed in the aforesaid planarization process to expose the conductive material 24.

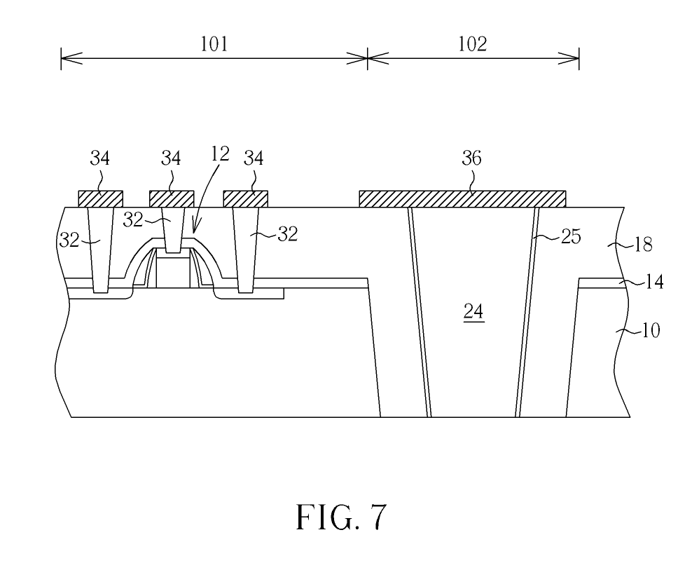

Thereafter, referring to FIG. 7, the back side, i.e. the side where the dielectric layer is not deposited, of the substrate 10 is subjected to a thinning process to expose the conductive material 24 of the TSV to accomplish a TSV structure. The thinning process may be performed through a polishing step, such as a CMP process, carried on the back side of the substrate 10. Thereafter, metal interconnects or pads 34 and 36 may be formed on the contacts and the conductive material 24 through conventional processes, such as, sputtering deposition and etch processes.

The method of fabricating a TSV structure according to the present invention may be applied in a Via-Middle process. That is, the TSV structure is fabricated between a FEOL process and a BEOL process of an IC fabrication, so that the redistribution layer and the bumper can be omitted. After forming the TSV structure, the BEOL process is performed to form the metal interconnection system and the contact pads which are electrically connected to the TSV to provide pathways for signal input/output.

In a process according to an embodiment of the present invention, a dielectric liner of a TSV structure is formed simultaneously with the formation of the interlayer dielectric. That is, the device region and the TSV structure share a dielectric layer, and accordingly a deposition process for forming a dielectric layer only for serving as a dielectric liner of a TSV structure as usually carried out in a conventional TSV fabrication can be omitted. Furthermore, a planarization process further carried out after the via hole is filled with a conductive material can also function as a planarization for forming the interlayer dielectric, and, accordingly, a planarization process for forming an interlayer dielectric can be further omitted.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a through silicon via (TSV) structure, comprising:
providing a substrate comprising a device region having a device disposed therein and a TSV region having a via hole disposed therein, the via hole having a sidewall and a bottom;
forming a dielectric layer to cover the device region and extend to a surface of the sidewall and a surface of the bottom of the via hole; and
filling the via hole having the dielectric layer covering the sidewall and the bottom with a first conductive material.

2. The method according to claim 1, wherein, when the via hole is disposed in the TSV region, a top surface of the device region has not been planarized, and the top surface of the device region is not flat.

3. The method according to claim 1, further comprising:
forming at least one contact within the dielectric layer in the device region.

4. The method according to claim 1, further comprising:
forming a patterned hard mask having at least one opening in the device region;
etching the dielectric layer through the at least one opening to form at least one contact hole, and
filling the at least one contact hole with a second conductive material to form at least one contact.

5. The method according to claim 1, further comprising:
forming a contact etch stop layer on the substrate and the device.

6. The method according to claim 1, wherein, filling the via hole having the dielectric layer covering the sidewall and the bottom with the first conductive material comprises:
filling the via hole with the first conductive material; and
planarizing the first conductive material together with the dielectric layer.

7. The method according to claim 1, further comprising:
forming a cap layer on the first conductive material and the dielectric layer.

8. The method according to claim 5, further comprising:
forming a cap layer on the first conductive material and the dielectric layer.

9. The method according to claim 6, further comprising:
forming a cap layer on the first conductive material and the dielectric layer.

10. The method according to claim 7, further comprising:
forming at least one contact through the cap layer and the dielectric layer in the device region.

11. The method according to claim 8, further comprising:
forming at least one contact through the cap layer and the dielectric layer in the device region.

12. The method according to claim 9, further comprising:
forming at least one contact through the cap layer and the dielectric layer in the device region.

13. The method according to claim 5, further comprising:
forming a cap layer on the first conductive material and the dielectric layer; and
forming at least one contact through the cap layer, the dielectric layer and the contact etch stop layer in the device region.

14. A through silicon via (TSV) structure, comprising:
a substrate comprising a device region and a TSV region having a via hole having a sidewall;
a dielectric layer disposed on the substrate to cover the device region and extend to cover a surface of the sidewall of the via hole; and
a conductive material filled into the via hole having the dielectric layer covering the sidewall.

15. The through silicon via structure according to claim 14, wherein the dielectric layer comprises a multi-layer structure.

16. The through silicon via structure according to claim 14, wherein the dielectric layer comprises a relatively thin layer of a relative dense material and a relatively thick layer of a relatively non-dense material.

17. The through silicon via structure according to claim 14, wherein the dielectric layer comprises a dielectric layer formed through a sub-atmospheric pressure chemical vapor deposition and a silicon oxide layer formed through a plasma enhanced chemical vapor deposition using tetraethoxysilane as a silicon source.

18. The through silicon via structure according to claim 14, further comprising:
a barrier layer disposed between the conductive material and the dielectric layer within the via hole.
